(19) United States
(12) Patent Application Publication
(10) Pub. No.: US 2011/0117695 A1
(43) Pub. Date: May 19, 2011

(54) FABRICATION METHOD OF ORGANIC THIN-FILM TRANSISTORS

(75) Inventors: Jung-Wei John Cheng, Kaohsiung (TW); Chang-Pen Chen, Kaohsiung (TW); Yeh-Min Lin, Kaohsiung (TW); Chun-Yi Lee, Kaohsiung (TW); Jeng-Rong Ho, Kaohsiung (TW)

(73) Assignee: METAL INDUSTRIES RESEARCH & DEVELOPMENT CENTRE, Kaohsiung (TW)

(21) Appl. No.: 12/650,369

(22) Filed: Dec. 30, 2009

(30) Foreign Application Priority Data
Nov. 18, 2009 (TW) 098139077

(51) Int. Cl. H01L 51/40

(52) U.S. Cl. 438/99; 438/151; 257/E51.007

(57) ABSTRACT

This invention discloses a fabrication method of organic thin-film transistors (OTFTs) using the micro-contact printing. The OTFT can be of the bottom-gate or top-gate configuration. The micro-contact printing operation of this fabrication method does not require clean-room environment and high processing temperature, and does not have the problem of 2D shrinkage of the printed patterns either. Furthermore, the pre-wetting technique employed in the micro-contact printing results in improved fidelity in the pattern transfer and solves the problems of pairing and cross-talking between neighboring patterns.

### BACKGROUND OF THE INVENTION

1. Field of the Invention

The present invention relates to a fabrication method of organic thin-film transistors (OTFTs), and more particularly, to a fabrication method of OTFTs using micro-contact printing.

2. Description of the Related Art

A conventional fabrication method of organic thin-film transistors (OTFTs) uses an inorganic substrate like silicon and forms required patterns by masking, exposure, development, and etching in a high vacuum, clean-room environment at high processing temperature. The process is complex and costly, unsuitable for mass production. In recent years, with the emergence of flexible electronics and advances in material technologies, direct coating methods for patterned organic thin films in a non-vacuum environment are developed to replace this conventional method for the fabrication of OTFTs. The results are much simpler, non-vacuum fabrication processes suitable for mass production.

Take silicon substrate as an example, a conventional fabrication process of an OTFT includes the following steps.

1. The silicon substrate is cleaned to remove native oxide and organic impurities, and then blow-dried with nitrogen (N₂) gas.

2. The pure silicon substrate is modified to a p⁺⁺ or n⁻⁻ substrate by ion-implantation, so as to form a desired gate electrode.

3. The cleaned silicon substrate is fed into a high-temperature furnace to grow silicon dioxide. The silicon dioxide is grown in an oxidation furnace by supplying oxygen gas and hydrogen gas in the process, and the processing temperature is generally 600° C.-1200° C.

4. A source/drain electrode is fabricated as follows: a photoresist is coated, a pattern is defined by exposure and development, a metal is plated, unwanted metal is directly removed by photoresist lift-off, and a desired electrode pattern is obtained.

5. An organic material is coated to form an organic active layer of the OTFT.

6. The organic material is baked and dried.

In the conventional fabrication process of an OTFT, since techniques such as thermal oxide growth in a high-temperature oxidation furnace or chemical vapor deposition (CVD) are used, the whole process is a high-temperature process, which is not suitable for fabricating an OTFT element on a flexible substrate, thereby limiting its application to flexible electronics.

Taiwan Patent No. 1307169 entitled “Method for fabricating organic thin-film transistors and product thereof” proposes a solution to improve the conventional fabrication process of OTFTs. However, this patent has the following disadvantages. Glass is used as the base material, and the low-temperature sputtering (physical vapor deposition, PVD) is employed. Although the PVD is operated at a temperature lower than 200° C., the temperature is still too high for ordinary flexible plastic base materials such as the polyethylene terephthalate (PET) with a heat resistance temperature of 120° C.

In addition, U.S. Pat. No. 7,485,507 B2 entitled “Organic thin-film transistor, method of fabricating the same, and flat panel display having the same” proposes a fabrication method of OTFT. This patent discloses a fabrication architecture for a top-gate OTFT, and patterning of the semiconductor layer and the insulating layer/protecting layer by a laser. However, this patent has the following disadvantages. The top-gate TFT architecture is complex, and the film is patterned by a conventional laser such as an excimer laser or a YAG laser, which easily causes excessive heat and cannot produce a refined pattern.

Consequently, there is a need for a fabrication method of OTFTs to solve the above-mentioned problems.

### SUMMARY OF THE INVENTION

The present invention provides a fabrication method of OTFTs, which includes forming an organic gate layer, an organic dielectric layer, an organic source/drain electrode layer, and an organic semiconductor layer on a substrate using micro-contact printing, so as to form an OTFT. The OTFT is a bottom-gate OTFT or a top-gate OTFT, depending on different sequences of the organic gate layer, the organic dielectric layer, the organic source/drain electrode layer, and the organic semiconductor layer formed on the substrate.

In the fabrication method of the present invention, all the functional layers of the OTFT are fabricated by micro-contact printing. The micro-contact printing operation of this fabrication method does not require clean-room environment. The pre-wetting technique employed in the micro-contact printing solves the problem of 2D shrinkage of the printed patterns and the problem of pairing and cross-talking between neighboring patterns, resulting in much improved fidelity in the pattern transfer, and solves the problems of pairing and cross-talking between neighboring patterns. Furthermore, the pre-wetting technique of the micro-contact printing enables low temperature, or even room temperature printing.

### BRIEF DESCRIPTION OF THE DRAWINGS

FIG. 1 is a schematic view of a bottom-gate OTFT according to the present invention;

FIG. 2 is a schematic view of another bottom-gate OTFT according to the present invention;

FIG. 3 is a schematic view of a top-gate OTFT according to the present invention;

FIG. 4 is a flow chart of a fabrication method of OTFTs according to the present invention; and

FIG. 5 is a schematic view of a process for forming each layer of the OTFT by using micro-contact printing according to the present invention.

### DETAILED DESCRIPTION OF THE INVENTION

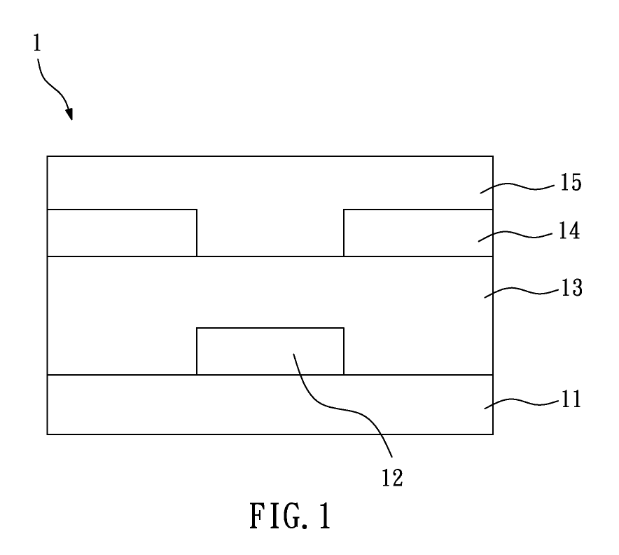

FIG. 1 is a schematic view of an OTFT according to the present invention. In the fabrication method of OTFTs of the present invention, an organic gate layer 12, an organic dielectric layer 13, an organic source/drain electrode layer 14, and an organic semiconductor layer 15 are formed on a substrate 11 by micro-contact printing, so as to form an OTFT 1. In this embodiment, the substrate 11 is a flexible or rigid substrate, and may be made of polyethylene terephthalate (PET), polycarbonate (PC), polyimide (PI), polyethylene naphthalate (PEN), polyethersulfone (PES), glass, silicon (Si), copper (Cu), or gold (Au). When a metallic substrate is used, there should be an insulation layer before fabrication of the OTFTs.

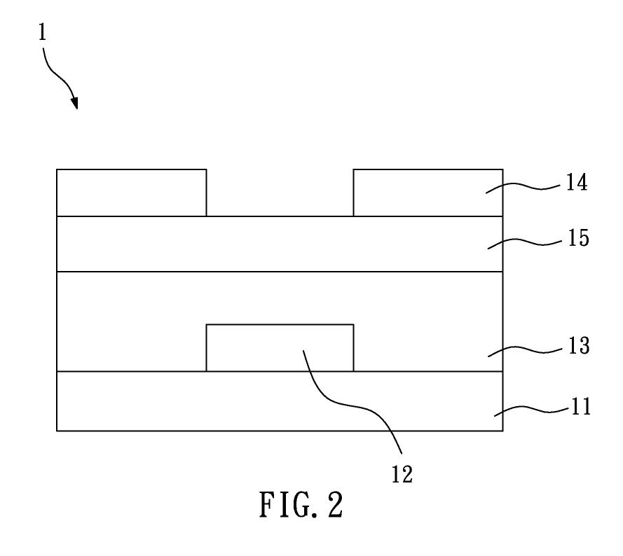

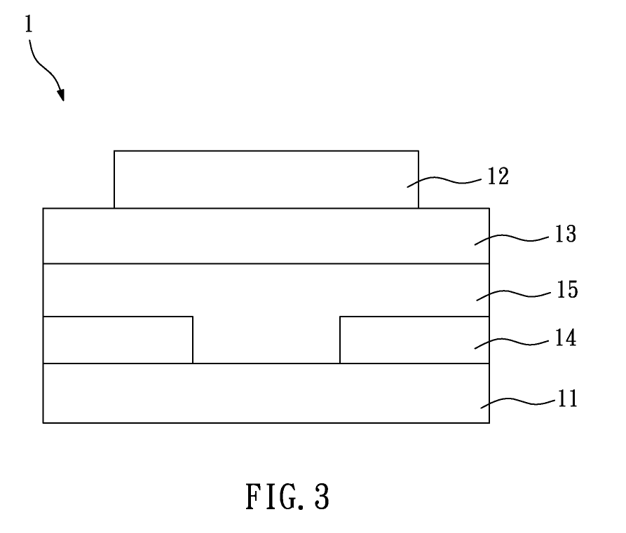

In this embodiment, the organic gate layer 12, the organic dielectric layer 13, the organic source/drain electrode layer 14, and the organic semiconductor layer 15 are sequentially formed on the substrate 11, so the OTFT 1 is a bottom-gate OTFT (as shown in FIG. 1). It should be noted that, in the method of the present invention, the organic gate layer 12, the organic dielectric layer 13, the organic semiconductor layer 15, and the organic source/drain electrode layer 14 may also be sequentially formed on the substrate 11 so that the OTFT 1 is another bottom-gate OTFT (as shown in FIG. 2), or the organic source/drain electrode layer 14, the organic semiconductor layer 15, the organic dielectric layer 13, and the organic gate layer 12 may be sequentially formed on the substrate 11 so that the OTFT 1 is a top-gate OTFT (as shown in FIG. 3).

The micro-contact printing is briefly described as follows.

The concept of the micro-contact printing is similar to that of an ordinary printing process, namely, a stamp having a pattern on a surface thereof is used to transfer ink molecules onto a substrate, thereby forming a desired pattern on the substrate. The difference between the micro-contact printing and ordinary printing process is that the micro-contact printing can achieve the transfer of patterns with micrometer and nanometer features.

The micro-contact printing can be generally divided into two categories, the chemisorption (self-assembled monolayer, SAM) based and physisorption based. In the case of the SAM based micro-contact printing, ink molecules and a substrate material are carefully selected so that the ink molecules can be bonded to the substrate by covalent bonds and self-assemble into an ordered monomolecular film in the transfer process. For example, alkanethiols ink molecules are bonded to a gold substrate by the covalent Au—S bonds. As to physisorption-based micro-contact printing, an elastomeric stamp having a low surface free energy (for example, a stamp made of poly(dimethyl siloxane), PDMS) is used. The elasticity allows the stamp to be easily brought into conformal contact with the substrate in the transfer process, and the low surface free energy of the stamp facilitates easy release of the ink molecules from the stamp in the transfer process.

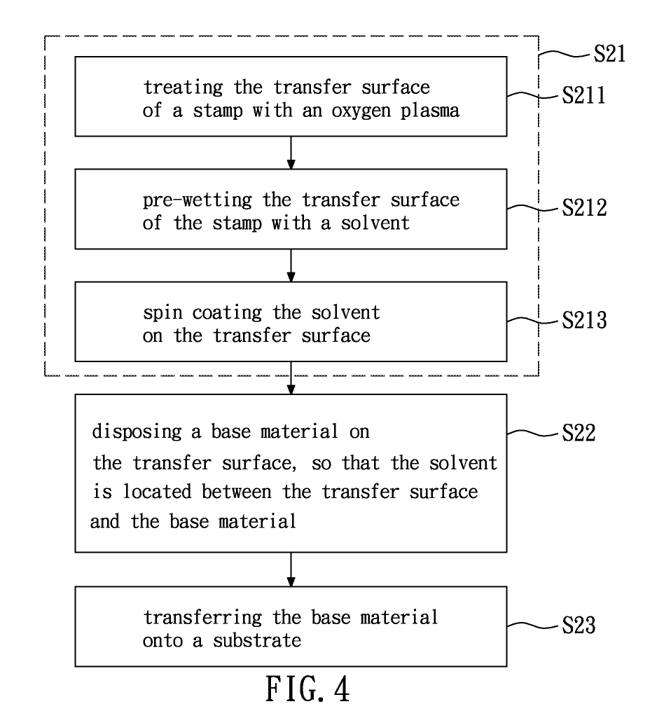

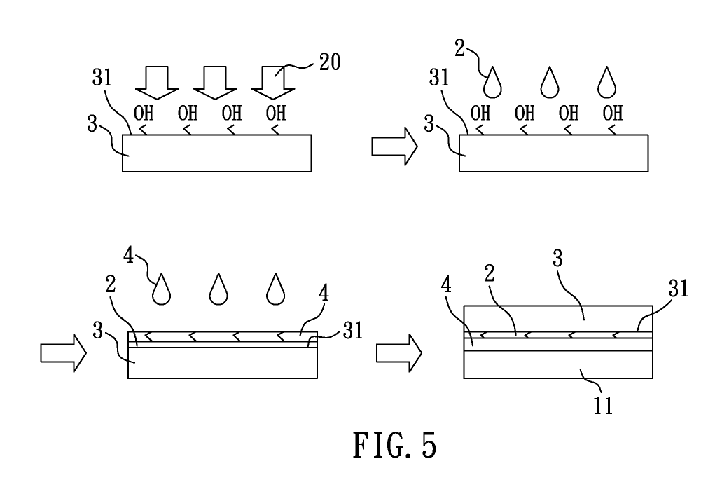

FIG. 4 is a flow chart of a fabrication method of OTFT according to the present invention; and FIG. 5 is a schematic view of a process for forming each layer of the OTFT by using the micro-contact printing according to the present invention. As shown in FIG. 's. 1, 4 and 5 in this embodiment, the micro-contact printing step is performed at room temperature, and each micro-contact printing step for forming each layer of the OTFT 1 includes the following steps. In step S21, a solvent 2 is disposed on a transfer surface 31 of a stamp 3. In step S22, a base material 4 is disposed on the transfer surface 31 (a liquid base material 4 is uniformly disposed on the transfer surface 31) so that the solvent 2 is located between the transfer surface 31 and the base material 4, and the base material 4 is used to form the organic gate layer 12, the organic dielectric layer 13, the organic source/drain electrode layer 14, or the organic semiconductor layer 15. In step S23, the base material 4 is transferred onto the substrate 11, so as to form the organic gate layer 12, the organic dielectric layer 13, the organic source/drain electrode layer 14, or the organic semiconductor layer 15.

Preferably, the stamp 3 is made of PDMS, and step S21 further includes the following steps. In step S211, the transfer surface 31 is treated with an oxygen (O₂) plasma 20. In step S212, the transfer surface 31 of the stamp 3 is pre-wet with the solvent 2. In step S213, the stamp 3 is spun, so as to uniformly distribute the solvent 2 on the transfer surface 31 by spin coating.

Here, step S211 of treating the transfer surface 31 with the O₂ plasma 20 aims to form —OH radicals on the transfer surface 31, so as to form a surface having a high surface free energy, thereby facilitating the adhesion work between the base material 4 to be transferred and the stamp 3. It should be noted that, if the interaction force between the base material 4 forming each layer of the OTFT 1 and the transfer surface 31 is smaller than the interaction force between the base materials 4 forming two neighboring layers of the OTFT 1, the step of treating the transfer surface 31 with the O₂ plasma 20 can be omitted.

The pre-wetting technique results in improved fidelity in the pattern transfer with a minimum dimension of (width, pitch)=(5 μm, 10 μm), and solves the problems of pairing and cross-talking between neighboring patterns. In addition, by applying a pre-wetting solvent, a smooth interface can be formed between the stamp 3 and the base material 4 to be transferred, so that the base material 4 can be uniformly coated on the transfer surface 31 of the stamp 3. Meanwhile, due to the presence of the smooth interface formed by the solvent 2 between the transfer surface 31 and the base material 4, the adhesion work between the base material 4 and the transfer surface 31 can be effectively reduced, thereby achieving transfer of the base material 4 to the substrate 11 at room temperature.

For example, when an organic conductive material poly(3,4-ethylenedioxythiophene doped with poly(styrene sulfonate) (PEDOT:PSS) (the base material 4) is uniformly coated on a PDMS stamp (the stamp 3) by spin coating, the solvent 2 may be purified water, so that a smooth interface is formed on the transfer surface 31 of the PDMS stamp 3, and PEDOT:PSS can be uniformly coated on the transfer surface 31 of the PDMS stamp 3. Due to the presence of the interface formed by purified water (the solvent 2) between the organic conductive material PEDOT:PSS and the PDMS stamp 3, the adhesion work between the PDMS stamp 3 and the organic conductive material PEDOT:PSS can be reduced, thereby achieving transfer at room temperature. Therefore, the method of the present invention can achieve transfer at room temperature without the need for any additional heating unit.

The bottom-gate OTFT 1 of FIG. 1 is taken as an example below, and the fabrication method of OTFTs of the present invention is illustrated in detail with reference to FIG. 's 4 and 5. In the bottom-gate OTFT 1 of FIG. 1, the organic gate layer 12, the organic dielectric layer 13, the organic source/drain electrode layer 14, and the organic semiconductor layer 15 are sequentially formed on the substrate 11. Fabrication processes of the layers of the bottom-gate OTFT 1 are described as follows.

Fabrication Process of the Organic Gate Layer 12:

1. The transfer surface 31 of the PDMS stamp 3 is treated with O₂ plasma so that —OH radicals are formed on the transfer surface 31, thereby forming a surface having a high surface free energy and facilitating the adhesion of the organic gate material PEDOT:PSS, the base material 4 to be transferred. (step S211)

2. Purified water is used as the pre-wetting solvent 2, and uniformly coated on the transfer surface 31 by spin coating. (step S212 and step S213)

3. The organic conductive material PEDOT:PSS is uniformly coated on the transfer surface 31 by spin coating. An interface is formed by purified water (the solvent 2) between the organic conductive material PEDOT:PSS and the PDMS stamp 3, thus reducing the adhesion work between the PDMS stamp 3 and the organic conductive material PEDOT:PSS. (step S22)

4. The organic conductive material PEDOT:PSS on the PDMS stamp 3 is transferred onto the substrate PET 11 by contact printing, so as to form the organic gate layer 12. (step S23)

Fabrication Process of the Organic Dielectric Layer 13:

1. The transfer surface 31 of the PDMS stamp 3 is treated with O₂ plasma so that —OH radicals are formed on the transfer surface 31, thereby forming a surface having a high surface free energy and facilitating the adhesion of the dielectric material poly(methyl methacrylate) (PMMA), the base material 4 to be transferred. (step S211)

2. Toluene is used as the pre-wetting solvent 2, and uniformly coated on the transfer surface 31 by spin coating. (step S212 and step S213)

3. An organic dielectric material PMMA is uniformly coated on the transfer surface 31 by spin coating. An interface is formed by toluene (the solvent 2) between the organic dielectric material PMMA and the PDMS stamp 3, thus reducing the adhesion work between the PDMS stamp 3 and the organic dielectric material PMMA. (step S22)

4. The organic dielectric material PMMA on the PDMS stamp 3 is transferred onto the gate layer 12 by contact printing, so as to form the organic dielectric layer 13. (step S23)

Fabrication Process of the Organic Source/Drain Electrode Layer 14:

1. The transfer surface 31 of the PDMS stamp 3 is treated with O₂ plasma so that —OH radicals are formed on the transfer surface 31, thereby forming a surface having a high surface free energy and facilitating the adhesion of the source/drain material PEDOT:PSS, the base material 4 to be transferred. The transfer surface 31 of the PDMS stamp 3 has a corresponding source/drain electrode pattern. (step S211)

2. Purified water is used as the pre-wetting solvent 2, and uniformly coated on the transfer surface 31 by spin coating. (step S212 and step S213)

3. The organic conductive material PEDOT:PSS is uniformly coated on the transfer surface 31 by spin coating. An interface is formed by purified water (the solvent 2) between the organic conductive material PEDOT:PSS and the PDMS stamp 3, thus reducing the adhesion work between the PDMS stamp 3 and the organic conductive material PEDOT:PSS. (step S22)

4. The organic conductive material PEDOT:PSS on the PDMS stamp 3 is transferred onto the organic dielectric layer 13 by contact printing, so as to form the organic source/drain electrode layer 14. The organic source/drain electrode layer 14 is located on two sides of a surface of the organic dielectric layer 13, and exposes a portion of the organic dielectric layer 13. (step S23)

Fabrication Process of the Organic Semiconductor Layer 15:

1. 1,2-dichlorobenzene (DCB) is used as the pre-wetting solvent 2, and uniformly coated on the transfer surface 31 by spin coating. (step S212 and step S213)

2. An organic semiconductor material poly(3-hexylthiophene) (P3HT), a p-type polymer/carbon-doped system, is uniformly coated on the transfer surface 31 by spin coating. A smooth interface is formed by DCB between the organic semiconductor material P3HT and the transfer surface 31, thus reducing the adhesion work between the transfer surface 31 and the organic semiconductor material P3HT. (step S22)

3. The organic semiconductor material P3HT on the PDMS stamp 3 is transferred onto the organic source/drain electrode layer 14 and a portion of the organic dielectric layer 13 by contact printing, so as to form the organic semiconductor layer 15. (step S23)

In this embodiment, the organic gate layer 12 is made of PEDOT:PSS, and the solvent 2 is purified water; in other applications, the organic gate layer 12 may also be made of polypyrrole (PPy), polythiophene (PT), polyaniline (PAn), poly(p-phenylene) (PPP), poly(phenylene vinylene) (PPV), or polythienylenevinylene (PTV). In this embodiment, the organic dielectric layer 13 is made of PMMA, and the solvent 2 is toluene; in other applications, the organic dielectric layer 13 may also be made of poly propylene, polyvinyl alcohol, polyvinyl phenol, or poly ethylene terephthalate. In this embodiment, the organic source/drain electrode layer 14 is made of PEDOT:PSS, and the solvent 2 is purified water; in other applications, the organic source/drain electrode layer 14 may also be made of PPy, PT, PAn, PPP, PPV, or PTV. In this embodiment, the organic semiconductor layer 15 is made of a P3HT, and the solvent 2 is DCB; in other applications, the organic semiconductor layer 15 may also be made of poly(3-alkylthiophene), polythienylenevinylene, or α-ω-dihexyl-quaterthiophene, or the organic semiconductor layer 15 may also be made of n-type phenyl-C61-butyric acid methyl ester (PCBM) or poly(cyclopentadithiophene) (PCPDT).

It should be understood that, in the other bottom-gate OTFT 1 as shown in FIG. 2 and the top-gate OTFT 1 shown in FIG. 3, the fabrication processes and materials of the organic gate layer 12, the organic dielectric layer 13, the organic semiconductor layer 15, and the organic source/drain electrode layer 14 are the same as those of the layers of the bottom-gate OTFT 1 shown in FIG. 1 except that the layers of the OTFT 1 are formed in a different sequence, so the details will not be described herein again.

In addition, in the OTFT 1 of the present invention, preferably, the substrate 11 has a surface roughness of 0.82±0.10 nm; the organic gate layer 12 has a surface roughness of 0.93±0.11 nm and a thickness of 102±2.06 nm; the organic dielectric layer 13 has a surface roughness of 1.12±0.15 nm and a thickness of 324±2.57 nm; the organic source/drain electrode layer 14 has a surface roughness of 1.56±0.54 nm and a thickness of 104±1.92 nm; and the organic semiconductor layer 15 has a surface roughness of 1.23±0.33 nm and a thickness of 16±1.37 nm.

In the fabrication method of the present invention, all the functional layers of the OTFT 1 are fabricated by the micro-contact printing. The micro-contact printing operation of this fabrication method does not require clean-room environment or high processing temperature, and does not have the problem of 2D shrinkage of the printed patterns either. Furthermore, the pre-wetting technique employed in micro-contact printing results in improved fidelity in the pattern transfer and solves the problems of pairing and cross-talking between neighboring patterns.

While embodiments of the present invention have been illustrated and described, various modifications and improvements can be made by those skilled in the art. The embodiments of the present invention are therefore described in an illustrative but not restrictive sense. It is intended that the present invention is not limited to the particular forms illustrated, and that all modifications that maintain the spirit and scope of the present invention are within the scope defined in the appended claims.

What is claimed is:

1. A fabrication method of organic thin-film transistors (OTFTs), comprising forming an organic gate layer, an organic dielectric layer, an organic source/drain electrode layer, and an organic semiconductor layer on a substrate using micro-contact printing, so as to form an OTFT, wherein the OTFT is a bottom-gate OTFT or a top-gate OTFT depending on different sequences of the organic gate layer, the organic dielectric layer, the organic source/drain electrode layer, and the organic semiconductor layer formed on the substrate.

2. The method according to claim 1, wherein the substrate is a flexible substrate.

3. The method according to claim 1, wherein the substrate is made of glass, polyethylene terephthalate (PET), polycarbonate (PC), polyimide (PI), polyethylene naphthalate (PEN), polyethersulfone (PES), silicon (Si), copper (Cu), or gold (Au).

4. The method according to claim 1, wherein the micro-contact printing step is performed at room temperature.

5. The method according to claim 1, wherein each micro-contact printing step comprises:
(a) disposing a solvent on a transfer surface of a stamp;
(b) disposing a base material on the transfer surface so that the solvent is located between the transfer surface and the base material, wherein the base material is used to form the organic gate layer, the organic dielectric layer, the organic semiconductor layer, or the organic source/drain electrode layer; and
(c) transferring the base material onto the substrate.

6. The method according to claim 5, wherein the stamp in step (a) is made of poly(dimethyl siloxane) (PDMS).

7. The method according to claim 5, wherein step (a) further comprises:
(a1) pre-wetting the transfer surface of the stamp with the solvent; and
(a2) spinning the stamp, so as to uniformly distribute the solvent on the transfer surface.

8. The method according to claim 7, wherein before step (a1), the method further comprises treating the transfer surface with an oxygen (O₂) plasma.

9. The method according to claim 7, wherein when poly(3,4-ethylenedioxythiophene) doped with poly(styrene sulfonate) (PEDOT:PSS) is used as the base material to form the organic gate layer, the solvent is purified water; when poly(methyl methacrylate) (PMMA) is used as the base material to form the organic dielectric layer, the solvent is toluene; when PEDOT:PSS is used as the base material to form the organic source/drain electrode layer, the solvent is purified water; and when poly(3-hexylthiophene) (P3HT) is used as the base material to form the organic semiconductor layer, the solvent is 1,2-dichlorobenzene (DCB).

10. The method according to claim 1, wherein the organic gate layer is made of PEDOT:PSS, polypyrrole (PPy), polythiophene (PT), polyaniline (PAn), poly(p-phenylene) (PPP), poly(phenylene vinylene) (PPV), or polythienylenevinylene (PTV); the organic dielectric layer is made of PMMA, poly propylene, polyvinyl alcohol, polyvinyl phenol, poly methyl methacrylate, or poly ethylene terephthalate; the organic source/drain electrode layer is made of PEDOT:PSS, PPy, PT, PAn, PPP, PPV, or PTV; and the organic semiconductor layer is made of a p-type polymer/carbon-doped system P3HT, poly(3-alkylthiophene), polythienylenevinylene, or α-ω-dihexyl-quaterthiophene, or made of n-type phenyl-C61-butyric acid methyl ester (PCBM) or poly(cyclopentadithiophene) (PCPDT).

11. The method according to claim 1, wherein the substrate has a surface roughness of 0.82±0.10; the organic gate layer has a surface roughness of 0.93±0.11 nm; the organic dielectric layer has a surface roughness of 1.12±0.15 nm; the organic source/drain electrode layer has a surface roughness of 1.56±0.54 nm; and the organic semiconductor layer has a surface roughness of 1.23±0.33 nm.

12. The method according to claim 1, wherein the organic gate layer has a thickness of 102±2.06 nm; the organic dielectric layer has a thickness of 324±2.57 nm; the organic source/drain electrode layer has a thickness of 104±1.92 nm; and the organic semiconductor layer has a thickness of 16±1.37 nm.

13. The method according to claim 1, wherein the organic gate layer, the organic dielectric layer, the organic source/drain electrode layer, and the organic semiconductor layer are sequentially formed on the substrate, so that the OTFT is a bottom-gate OTFT.

14. The method according to claim 1, wherein the organic gate layer, the organic dielectric layer, the organic semiconductor layer, and the organic source/drain electrode layer are sequentially formed on the substrate, so that the OTFT is a bottom-gate OTFT.

15. The method according to claim 1, wherein the organic source/drain electrode layer, the organic semiconductor layer, the organic dielectric layer, and the organic gate layer are sequentially formed on the substrate, so that the OTFT is a top-gate OTFT.
